(19) United States
(12) Patent Application Publication
(10) Pub. No.: US 2012/0182677 A1
(43) Pub. Date: Jul. 19, 2012

(54) PORTABLE TERMINAL TRANSFORMABLE INTO BRACELET

(75) Inventor: Mun-Deock SEO, Seoul (KR)

(73) Assignee: PANTECH CO., LTD., Seoul (KR)

(21) Appl. No.: 13/341,387

(22) Filed: Dec. 30, 2011

(30) Foreign Application Priority Data
Jan. 18, 2011 (KR) 10-2011-0005145

(51) Int. Cl. H05K 5/02

(52) U.S. Cl. 361/679.01

(57) ABSTRACT

A portable terminal transformable into the form of a bracelet is provided and includes a first flexible body, a second flexible body, a first link body, a second link body, hinge modules and a battery. A flexible display is provided on at least one of the first and second flexible bodies. The hinge modules are installed between the first link body and the second link body at both ends of the first flexible body and the second flexible body to rotate the first link body and the second link body such that the first flexible body and the second flexible body are opened into the form of a bracelet and are closed into the form of a bar.

### CROSS-REFERENCE TO RELATED APPLICATION

This application claims priority to and the benefit under 35 U.S.C. §119(a) of Korean Patent Application No. 10-2011-0005145, filed on Jan. 18, 2011, which is hereby incorporated by reference for all purposes as if fully set forth herein.

### BACKGROUND

1. Field

The following description relates to a portable terminal, and more particularly, to a portable terminal alternately transformable into the form of a bar and a bracelet.

2. Discussion of the Background

A mobile phone is a type of mobile terminal that serves as a personal communication device configured to perform a voice call and a wireless communication while a user is carrying the mobile phone. Due to the increase in various user demands, the mobile phone is an integrated product having various kinds of operations, such as MP3 players, digital cameras, digital multimedia broadcasting (DMB) receivers, and personal digital assistant (PDA), in addition to general communication operations. In addition, the mobile phone is implemented in various forms to satisfy the demands of users in terms of design. For example, the mobile phone may be a watch type mobile phone attachable to a wrist of a user.

However, while the conventional watch type mobile phone is attachable to a wrist of a user, providing enhanced portability, it may limit increasing the size of a display. In other words, the application of the watch type mobile phone is limited only to a small sized display, and thus the mobile phone has a low efficiency of use. Accordingly, there is a need for a mobile phone enhancing the portability and utilization while decreasing the limitations of a display size.

### SUMMARY

Exemplary embodiments of the present invention provide a portable terminal transformable in the form of a bracelet, capable of enhancing the portability and utilization.

Exemplary embodiments of present invention also provide a portable terminal transformable in the form of a bracelet.

Additional features of the invention will be set forth in the description which follows, and in part will be apparent from the description, or may be learned by practice of the invention.

An exemplary embodiment of the present invention discloses a portable terminal transformable into a bracelet, the portable terminal including: a first flexible body and a second flexible body which face each other and at least one of which is provided with a flexible display; first link bodies each connected to an end of the first flexible body; second link bodies each connected to an end of the second flexible body; hinge modules each installed between the first link body and the second link body at the ends of the first flexible body and the second flexible body to rotate the first link body and the second link body; and a battery to provide power.

An exemplary embodiment of the present invention discloses a portable terminal transformable into a bracelet, the terminal including: a first flexible body and a second flexible body which face each other and at least one of which is provided with a flexible display; a link body connected to an end of the first flexible body; a second link body connected to an end of the second flexible body; a hinge module installed between the first link body and the second link body at the end of the first flexible body and the second flexible body to rotate the first link body and the second link body; and a battery to provide power.

It is to be understood that both the foregoing general description and the following detailed description are exemplary and explanatory and are intended to provide further explanation of the invention as claimed. Other features and aspects will be apparent from the following detailed description, the drawings, and the claims.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a perspective view of a portable terminal transformable into the form of a bracelet according to an exemplary embodiment.

FIG. 2 is a perspective view of a portable terminal that is transformed into a bracelet state according to an exemplary embodiment.

FIG. 3 is a cross sectional view of a portable terminal according to an exemplary embodiment.

FIG. 4 is a perspective view of a hinge module according to an exemplary embodiment.

FIG. 5 is an exploded perspective view of a hinge module according to an exemplary embodiment.

FIG. 6 is a perspective view of an operation of a hinge module according to an exemplary embodiment.

FIG. 7 is a perspective view of an operation of a hinge module according to an exemplary embodiment.

FIG. 8 is a perspective view of a hinge module according to an exemplary embodiment.

FIG. 9 is a view of a portable terminal having a laminated battery according to an exemplary embodiment.

FIG. 10 is a view of a portable terminal having a block type battery according to an exemplary embodiment.

FIG. 11 is a view of a portable terminal having an integrated battery according to an exemplary embodiment.

FIG. 12 is a view of a portable terminal having a detachable battery according to an exemplary embodiment.

### DETAILED DESCRIPTION OF THE ILLUSTRATED EMBODIMENTS

Exemplary embodiments are described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements. It will be understood that when an element is referred to as being “on” or “connected to” another element, it can be directly on or directly connected to the other element, or intervening elements may be present. In contrast, when an element is referred to as being “directly on” or “directly connected to” another element there are no intervening elements present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

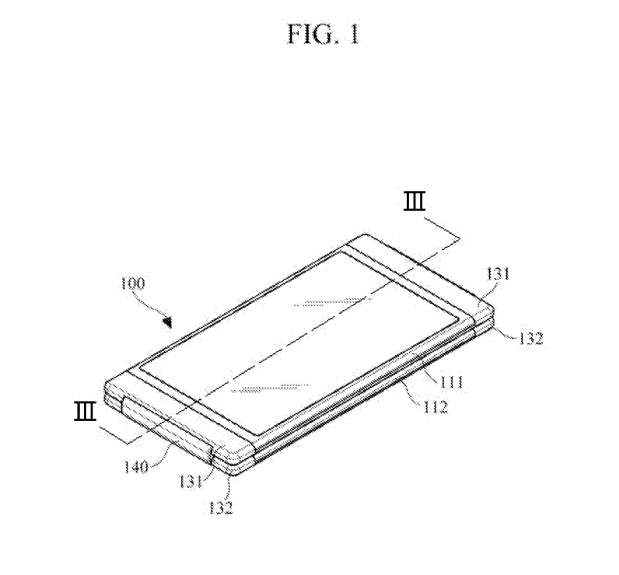

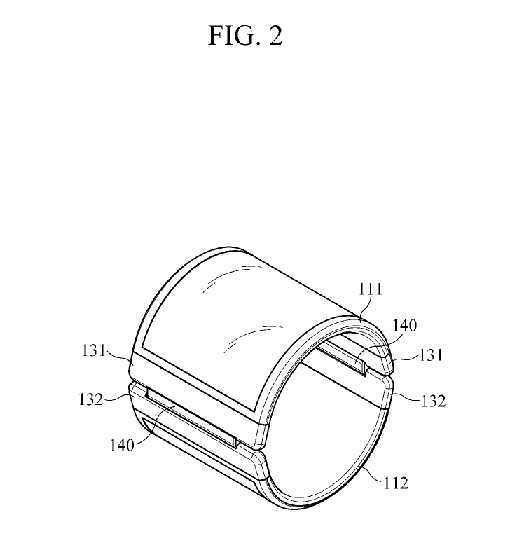

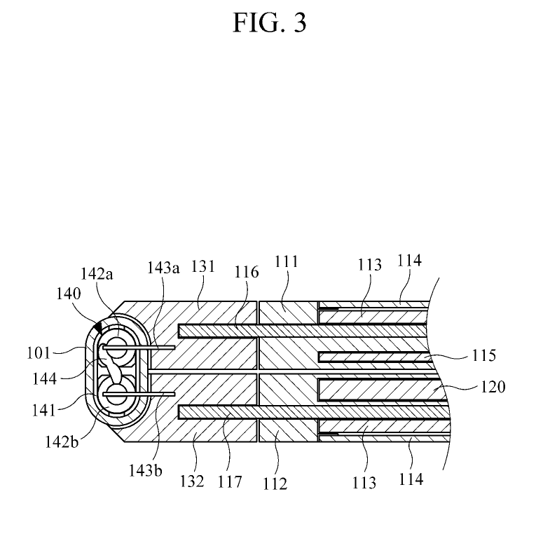

FIG. 1 is a perspective view of a portable terminal transformable into the form of a bracelet according to an exemplary embodiment. FIG. 2 is a perspective view of a portable terminal that is transformed into a bracelet state according to an exemplary embodiment. FIG. 3 is a cross sectional view of a portable terminal, taken along the line III-III of FIG. 1, according to an exemplary embodiment.

As shown in FIG. 1, FIG. 2 and FIG. 3, a portable terminal 100 transformable into the form of a bracelet includes a first flexible body 111, a second flexible body 112, a battery 120, first link bodies 131, second link bodies 132 and hinge modules 140.

The first flexible body 111 and the second flexible body 112 are configured to deform to be bent. The first flexible body 111 and the second flexible body 112 are disposed facing each other. A flexible display (FPC) 113 is provided on at least one of the first flexible body 111 and the second flexible body 112.

The flexible display 113 is a display that deforms to be bent or rolled due to its flexible property. The flexible display 113 may be a liquid crystal display (LCD) or an organic light emitting diode (OLED) display.

The flexible display 113 is disposed on one of opposite outer surfaces of the first flexible body 111, not facing the second flexible body 112 or on one of opposite outer surface of the second flexible body 112, not facing the first flexible body 111. If the flexible displays 113 are provided on both of the first flexible body 111 and the second flexible body 112, the portable terminal 100 achieves a dual display, thereby enhancing the utilization. The flexible displays 113 are able to independently display an image.

A touch window 114 may be installed on an upper part of the flexible display 113 to input commands through a touch scheme. A printed circuit board 115 may be accommodated in the first flexible body 111 or the second flexible body 112. The printed circuit board 115 may be a flexible printed circuit board (FPCB). The first flexible body 111 and the second flexible body 112 are electrically connected to a flexible printed circuit board 115 passing through the hinge module 140. The battery 120 is configured to provide a power source to components, such as the flexible display 113.

The first link bodies 131 are a pair of link bodies. Each first link body 131 is connected to an end of the first flexible body 111. The first link bodies 131 may be configured to connect the first flexible body 111 to the hinge module 140. The first link bodies 131 may be formed using a rigid body, and support both ends of the first flexible body 111. The second link bodies 132 are a pair of link bodies. Each second link body 132 is connected to an end of the second flexible body 112. The second link bodies 132 are configured to connect the second flexible body 112 to the hinge module 140. The second link bodies 132 may be formed using a rigid body support the both ends of the second flexible body 112.

Each of the hinge modules 140 is installed between the first link body 131 and the second link body 132 at both ends of the first flexible body 111 and the second flexible body 112 to rotate the first link body 131 and the second link body 132. In other words, at least one hinge module 140 is installed between the first link body 131 and the second link body 132, which are disposed on one side of the first flexible body 111 and the second flexible body 112, to rotate the first link body 131 and the second link body 132 such that the first link body 131 and the second link body 132 move away from each other or close to each other.

In addition, at least one hinge module 140 is installed between the first link body 131 and the second link body 132, which are disposed on another side of the first flexible body 111 and the second flexible body 112, to rotate the first link body 131 and the second link body 132 such that the first link body 131 and the second link body 132 move away from each other or close to each other. The hinge module 140 is accommodated in a casing 101 that is disposed on a side of the first link body 131 and the second link body 132 not adjacent the first flexible body 111 and the second flexible body 112.

Accordingly, as shown in FIG. 1, in a state in which the first flexible body 111 and the second flexible body 112 are closed into the form of a bar, if a force is laterally applied from the both ends of the first flexible body 111 and the second flexible body 112 to the middle parts of the first flexible body 111 and the second flexible body 112, the first link body 131 and the second link body 132 rotate away from each other due to the operation of the hinge module 140. In other words, the first flexible body 111 and the second flexible body 112 move away from each other and the portable terminal 100 deforms into the form of a bracelet as shown in FIG. 2.

In the bracelet state, if a force is applied inwardly to the first flexible body 111 and the second flexible body 112 from the outer surfaces of the first flexible body 111 and the second flexible body 112, the pair of the first link body 131 and the second link body 132 rotate, at the both ends of the first flexible body 111 and the second flexible body 112, and move adjacent to each other due to the operation of the hinge module 140. In other words, the first flexible body 111 and the second flexible body 112 move adjacent to each other and the portable terminal 100 deforms into the form of a bar as shown in FIG. 1.

As described above, the portable terminal 100 is transformable into various forms such as a bar or a bracelet, thereby enhancing the utilization. In addition, the user may transform the portable terminal 100 into the form of a bracelet and wear the portable terminal 100 in a bracelet state, thereby enhancing the portability and user's convenience. In addition, the portable terminal 100 has a structure allowing the flexible display 113 to be attached to the outer surfaces of each of the first flexible body 111 and the second flexible body 112, thereby enlarging a display area and thus enhance the utilization of the portable terminal 100.

As shown in FIG. 3, the portable terminal 100 may further include a first support plate 116 and a second support plate 117. The first support plate 116 has a middle part extending inside the first flexible body 111 and an end part fixed to each of the first link bodies 131. The first support plate 116 may be formed using an elastic material.

The second support plate 117 has a middle part extending inside the second flexible body 112 and an end part fixed to each of the second link bodies 132. The second support plate 117 is formed using elastic material. The first and support plate 116 and the second support plate 117 are configured to maintain the first flexible body 111 and the second flexible body 112 in a flat state if the first flexible body 111 and the second flexible body 112 are deformed into the form of a bar, and maintain the first flexible body 111 and the second flexible body 112 in a bent state if the first flexible body 111 and the second flexible body 112 are deformed into the form of a bracelet.

The hinge modules 140 are configured to allow the first flexible body 111 and the second flexible body 112 to move away from each other or adjacent to each other simultaneously. In other words, the hinge module 140 rotates the first link body 131 and the second link body 132 in opposite directions and with a substantially identical or similar rotation angle, so that the first flexible body 111 and the second flexible body 112 are bent or stretched symmetrically around a joining surface of the first flexible body 111 and the second flexible body 112.

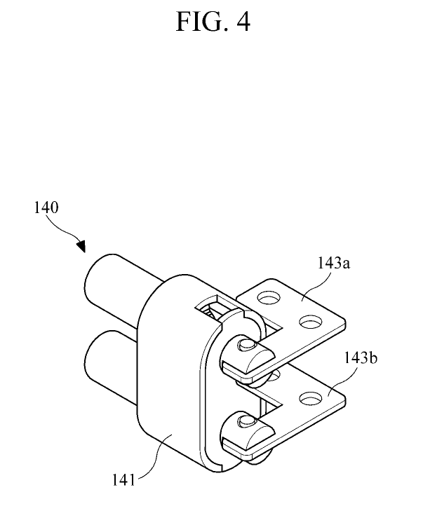

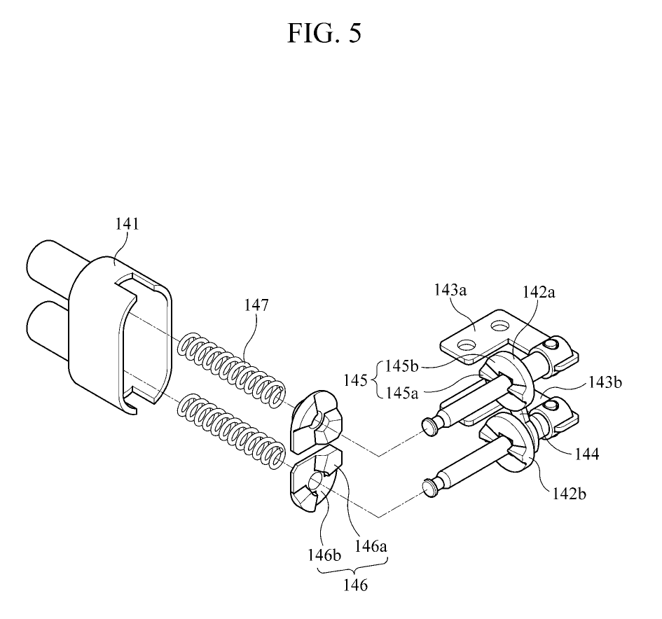

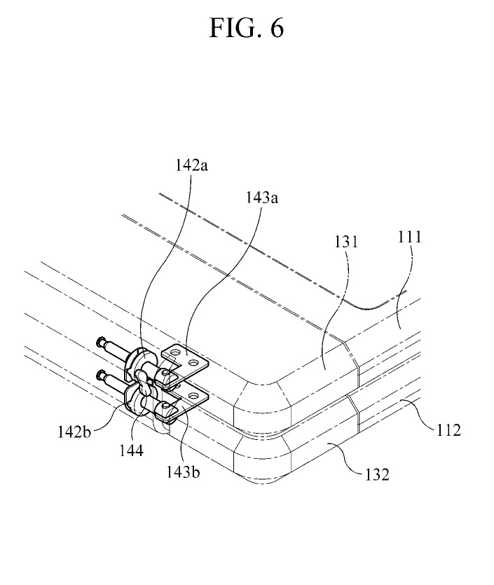

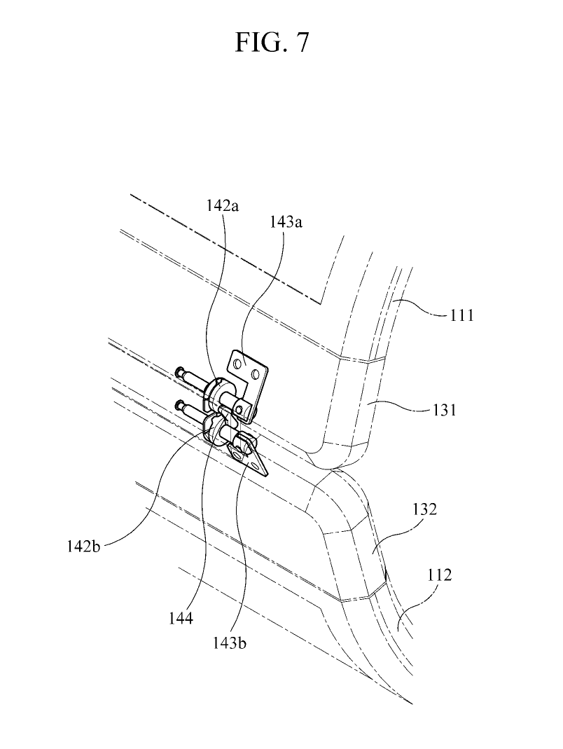

For example, each of the hinge modules 140 may have a configuration shown in FIG. 4, FIG. 5, FIG. 6 and FIG. 7. FIG. 4 is a perspective view of a hinge module according to an exemplary embodiment. FIG. 5 is an exploded perspective view of a hinge module according to an exemplary embodiment. FIG. 6 is a perspective view of an operation of a hinge module according to an exemplary embodiment. FIG. 7 is a perspective view of an operation of a hinge module according to an exemplary embodiment.

As shown in FIG. 4, FIG. 5, FIG. 6 and FIG. 7, each of the hinge modules 140 includes a hinge housing 141, a first rotation member 142a, a second rotation member 142b, a first fixed bracket 143a, a second fixed bracket 143b and an interlocking member 144. The hinge housing 141 is disposed outside the first link body 131 and the second link body 132 while making contact with the first link body 131 and the second link body 132. The hinge housing 141 rotatably supports the first rotation member 142a and the second rotation member 142b while accommodating the first rotation member 142a and the second rotation member 142b.

The first rotation member 142a and the second rotation member 142b are rotatably supported inside the hinge housing 141. The first rotation member 142a and the second rotation member 142b are each provided with a disc and a rotary shaft passing through both sides of the disc. The outer rim of the first rotation member 142a faces the outer rim of the second rotation member 142b.

The first fixed bracket 143a has one end fixed to the rotary shaft of the first rotation member 142a and another end fixed to the first link body 131. The first fixed bracket 143a rotates according to the rotation of the first rotation member 142a, thereby rotating the first link body 131. The second fixed bracket 143b has one end fixed to the rotary shaft of the second rotation member 142b and another end fixed to the second link body 132. The second fixed bracket 143b rotates according to the rotation of the second rotation member 142b, thereby rotating the second link body 132.

As shown in FIG. 6 and FIG. 7, the interlocking member 144 has one end rotatably connected to the first rotation member 142a and another end rotatably connected to the second rotation member 142b to simultaneously rotate the first rotation member 142a and the second rotation member 142b. In other words, the interlocking member 144 connects the first rotation member 142a to the second rotation member 142b such that the first rotation member 142a and the second rotation member 142b rotate in opposite directions and with a substantially identical or similar rotation angle. Accordingly, the first flexible body 111 and the second flexible body 112 are bent or stretched symmetrically around a joining surface of the first flexible body 111 and the second flexible body 112.

Meanwhile, the hinge module 140 maintains the first flexible body 111 and the second flexible body 112 in a state in which the first flexible body 111 and the second flexible body 112 are fully opened into the form of a bracelet or fully closed into the form of a bar. In addition, the hinge module 140 allows the first flexible body 111 and the second flexible body 112 to be automatically opened or closed if the first flexible body 111 and the second flexible body 112 are deformed beyond a specific extent. To this end, the hinge module 140 may include fixed cams 145, moving cams 146 and elastic members 147.

One of the fixed cams 145 is formed to correspond to one side of the first rotation member 142a. The other fixed cam 145 is formed to correspond to one side of the second rotation member 142b. Each of the fixed cams 145 has a first crest part 145a and a first trough part 145b. The first crest part 145a includes a pair of crest parts that are spaced apart from each other while interposing the first trough part 145b therebetween. The moving cams 146 are disposed facing the fixed cams 145. Each of the moving cams 146 has a second crest part 146a and a second trough part 146b. The second crest part 146a is engaged with the first trough part 145b. The second trough part 146b is engaged with the first crest part 145a. If the first flexible body 111 and the second flexible body 112 are fully opened or fully closed, the first crest part 145a is engaged with the second trough part 146b and the first trough part 145b is engaged with the second crest part 146a.

The elastic members 147 are configured to apply an elastic force to the moving cams 146 in a direction in which the moving cams 146 are pushed toward the fixed cams 145. The elastic member 147 maintains the engagement state between the first crest part 145a and the second trough part 146b and between the first trough part 145b and the second crest part 146a. Accordingly, the first flexible body 111 and the second flexible body 112 are maintained in a fixed state in which the first flexible body 111 and the second flexible body 112 are fully opened or fully closed.

If the engagement state between the first crest part 145a and the second trough part 146b and between the first trough part 145b and the second crest part 146a overcome, the elastic member 147 allows the first flexible body 111 and the second flexible body 112 to be automatically opened or closed through a restoring force. The elastic member 147 may be a compression coil spring.

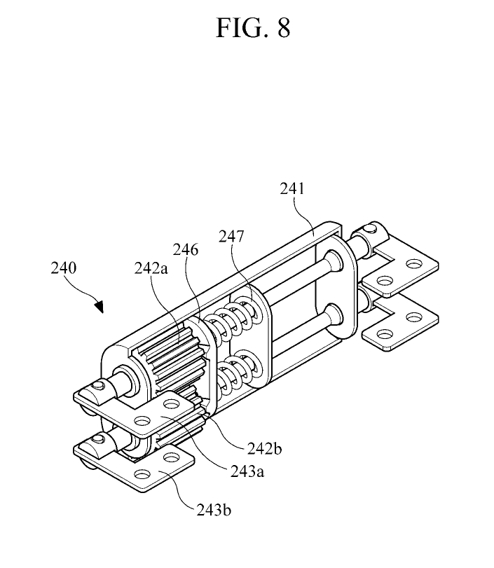

FIG. 8 is a perspective view of a hinge module according to an exemplary embodiment.

As shown in FIG. 8, a hinge module 240 according to an exemplary embodiment includes a first gear member 242a and a second gear member 242b instead of the first rotation member 142a and the second rotation member 142b. The first gear member 242a and the second gear member 242b are rotatably supported in a hinge housing 241. A first fixed bracket 243a is fixed to a rotary shaft of the first gear member 242a and a second fixed bracket 243b is fixed to a rotary shaft of the second gear member 242b. The first gear member 242a and the second gear member 242b rotate through engagement with each other. Therefore, the first gear member 242a and the second gear member 242b rotate in opposite directions and with the same or similar rotation angle, so that the first flexible body 111 and the second flexible body 112 are bent or stretched symmetrically around a joining surface of the first flexible body 111 and the second flexible body 112.

Fixed cams may be formed at one side of the first gear member 242a and the second gear member 242b, respectively. The fixed cams maintain a state in which the first flexible body 111 and the second flexible body 112 are fully opened into the form of a bracelet or fully closed into the form of a bar. In addition, the fixed cams allow the first flexible body 111 and the second flexible body 112 to be automatically opened or closed if the first flexible body 111 and the second flexible body 112 deform to a specific extent. Moving cams 246 are each disposed to face each first cam. Elastic members 247 are installed to apply an elastic force to the moving cams 246 such that the moving cams 246 are pushed toward the fixed cams. The fixed cam, the moving cam 246 and the elastic member 247 have the same operations as those of the fixed cam 145, the moving cam 146 and the elastic member 147, respectively, described above.

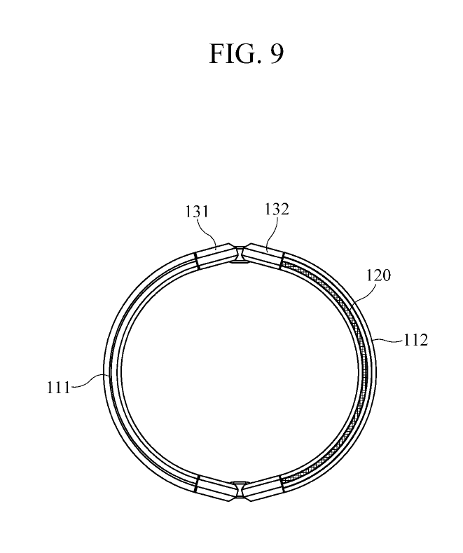

FIG. 9 is a view of a portable terminal having a laminated battery according to an exemplary embodiment

As shown in FIG. 9, the battery 120 according to an exemplary embodiment may be a laminated battery deformable to be bent. The laminated battery may be provided in the form of thin films and obtained by performing a laminating scheme using electrode elements and electrolyte elements. The laminated battery 120 is provided on at least one of the first flexible body 111 and the second flexible body 112, for example, the laminated battery 120 may be provided on the second flexible body 112, as shown in FIG. 9. If the second flexible body 112 deforms to be bent, the laminated battery 120 is flexibly bent together with the second flexible body 112 without disturbing the bending deformation of the second flexible body 112.

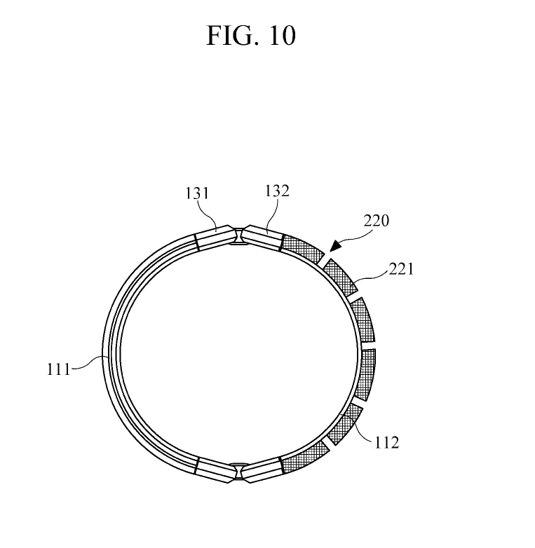

FIG. 10 is a view of a portable terminal having a block type battery according to an exemplary embodiment.

As shown in FIG. 10, a battery 220 according to an exemplary embodiment may be a block type battery that includes a plurality of block cells 221 to deform to be bent. The block type battery 220 is provided on at least one of the first flexible body 111 and the second flexible body 112, for example, the block type battery 220 may be provided on the second flexible body 112, as shown in FIG. 10. The block cells 221 are electrically connected to each other. The block cell 221 has a size which does not affect the bending deformation of the second flexible body 112.

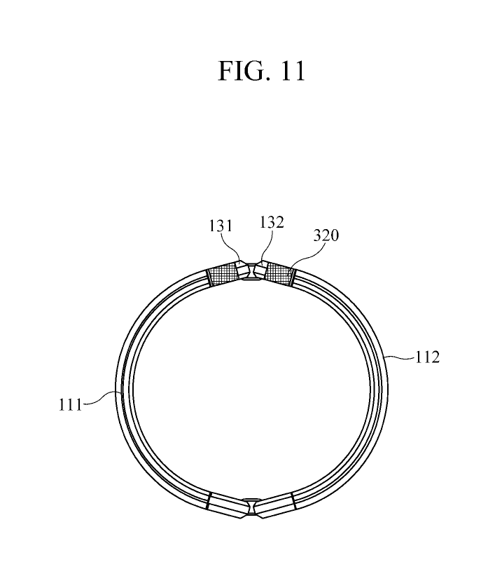

FIG. 11 is a view of a portable terminal having an integrated battery according to an exemplary embodiment.

As shown in FIG. 11, a battery 320 according to an exemplary embodiment may be an integrated battery accommodated in at least one of the first link body 131 and the second link body 132. The integrated battery 320 is provided in at least one of the first link body 131 and the second link body 132 instead of the first flexible body 111 or the second flexible body 112, thereby reducing the size of the first flexible body 111 and/or the second flexible body 112.

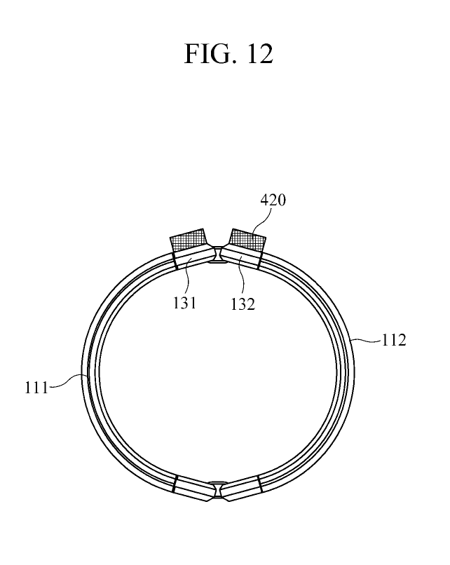

FIG. 12 is a view of a portable terminal having a detachable battery according to an exemplary embodiment.

As shown in FIG. 12, a battery 420 according to an exemplary embodiment may be a detachable battery that is detachably connected to at least one of the first link body 131 and the second link body 132. A user may replace the battery more easily, thereby enhancing user's convenience.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A portable terminal transformable into a bracelet, the portable terminal comprising:
a first flexible body and a second flexible body which face each other and at least one of which is provided with a flexible display;
first link bodies each connected to an end of the first flexible body;
second link bodies each connected to an end of the second flexible body;
hinge modules each installed between the first link body and the second link body at the ends of the first flexible body and the second flexible body to rotate the first link body and the second link body; and
a battery to provide power.

2. The portable terminal of claim 1, wherein each hinge module is configured to rotate the first link body and the second link body in opposite directions and with a substantially identical or similar rotation angle such that the first flexible body and the second flexible body are simultaneously opened or closed.

3. The portable terminal of claim 2, wherein the each hinge module comprises:
a hinge housing;
a first rotation member and a second rotation member that are rotatably supported in the hinge housing;
a first fixed bracket having one end fixed to a rotary shaft of the first rotation member and another end connected to the first link body;
a second fixing bracket having one end fixed to a rotary shaft of the second rotation member and another end connected to the second link body; and
an interlocking member having one end rotatably connected to the first rotation member and another end rotatably connected to the second rotation member such that the first rotation member and the second rotation member are simultaneously rotated.

4. The portable terminal of claim 3, wherein each hinge module further comprises:
fixed cams each connected to one side of the first rotation member and one side of the second rotation members, respectively, and each forming a first crest part and a first trough part thereon;
moving cams disposed facing the fixed cams, respectively, and each having a second trough part and a second crest part that engage the first crest part and the first trough part of the fixed cam, respectively;
elastic members configured to apply elastic force to the moving cams such that the moving cams are pushed toward the fixed cams,
wherein the first crest part of the fixed cams engage the second trough part of the moving cams and the first trough part of the fixed cams engage the second crest part of the moving cams if the first flexible body and the second flexible body are fully opened or fully closed.

5. The portable terminal of claim 2, wherein each hinge module comprises:
a hinge housing;
a first gear member and a second gear member that are rotatably supported in the hinge housing and rotate through engagement with each other;
a first fixed bracket having one end connected to a rotary shaft of the first gear member and another end connected to the first link body; and
a second fixed bracket having one end connected to a rotary shaft of the second gear member and another end connected to the second link body.

6. The portable terminal of claim 5, wherein each hinge module further comprises:
fixed cams which are installed at one side of the first gear member and one side of the second gear member, respectively, each having a first crest part and a first trough part;
moving cams each having a second trough part and a second crest part that are engage the first crest part and the first trough part, respectively; and
elastic members configured to apply elastic force to the moving cams such that the moving cams are pushed toward the fixed cams,
wherein the first crest part is engaged with the second trough part and the first trough part is engaged with the second crest part if the first flexible body and the second flexible body are fully opened or fully closed.

7. The portable terminal of claim 1, wherein the battery is provided on at least one of the first flexible body and the second flexible body and is a block type battery including a plurality of block cells deformable to be bent.

8. The portable terminal of claim 1, wherein the battery is provided on at least one of the first flexible body and the second flexible body and is a laminated battery deformable to be bent.

9. The portable terminal of claim 1, wherein the battery is an integrated battery accommodated in at least one of the first link body and the second link body.

10. The portable terminal of claim 1, wherein the battery is a detachable battery that is detachable to at least one of the first link body and the second link body.

11. The portable terminal of claim 1, further comprising:
a first support plate which is formed using elastic material and has a middle part extending inside the first flexible body and each end part connected to the first link bodies, respectively; and
a second support plate which is formed using elastic material and has a middle part extending inside the second flexible body and both end parts connected to the second link bodies.

12. A portable terminal transformable into a bracelet, the terminal comprising:
a first flexible body and a second flexible body which face each other and at least one of which is provided with a flexible display;
a link body connected to an end of the first flexible body;
a second link body connected to an end of the second flexible body;
a hinge module installed between the first link body and the second link body at the end of the first flexible body and the second flexible body to rotate the first link body and the second link body; and
a battery to provide power.

13. The portable terminal of claim 12, wherein the hinge module rotates the first link body and the second link body such that the first flexible body and the second flexible body open into the form of a bracelet and close into the form of a bar.

14. The portable terminal of claim 13, wherein the hinge module is configured to rotate the first link body and the second link body in opposite directions and with a substantially identical or similar rotation angle such that the first flexible body and the second flexible body are simultaneously opened or closed.

15. The portable terminal of claim 14, wherein the hinge module comprises:
a hinge housing;
a first rotation member and a second rotation member that are rotatably supported in the hinge housing;
a first fixed bracket having one end fixed to a rotary shaft of the first rotation member and another end connected to the first link body;
a second fixing bracket having one end fixed to a rotary shaft of the second rotation member and another end connected to the second link body; and
an interlocking member having one end rotatably connected to the first rotation member and another end rotatably connected to the second rotation member such that the first rotation member and the second rotation member are simultaneously rotated.

16. The portable terminal of claim 15, wherein the hinge module further comprises:
a first fixed cam connected to one side of the first rotation member, forming a first crest part and a first trough part thereon;
a second fixed cam connected to one side of the second rotation member, forming a first crest part and a first trough part thereon;
a first moving cam disposed facing the first fixed cam having a second trough part and a second crest part that engage the first crest part and the first trough part of the first fixed cam;
a second moving cam disposed facing the second fixed cam having a second trough part and a second crest part that engage with the first crest part and the first trough part of the second fixed cam; and
elastic members configured to apply elastic force to the first moving cam and the second moving cam such that the first moving cam and the second moving cam are pushed toward the first fixed cam and the second moving cam, respectively,
wherein the first crest part of the first fixed cam and the second fix cam engage the second trough part of the first moving cam and the second moving cam, and the first trough part of the first fixed cam and the second fix cam engage the second crest part of the first moving cam and the second moving cam if the first flexible body and the second flexible body are fully opened or fully closed.

17. The portable terminal of claim 14, wherein the hinge module comprises:
a hinge housing;
a first gear member and a second gear member that are rotatably supported in the hinge housing and rotate through engagement with each other;
a first fixed bracket having one end connected to a rotary shaft of the first gear member and another end connected to the first link body; and
a second fixed bracket having one end connected to a rotary shaft of the second gear member and another end connected to the second link body.

18. The portable terminal of claim 17, wherein the hinge module further comprises:
a first fixed cam connected to one side of the first gear member having a first crest part and a first trough part;
a second fixed cam connected to one side of the second gear member having a first crest part and a first trough part;
a first moving cam having a second trough part and a second crest part that engage the first crest part and the first trough part, respectively, of the first fixed cam;
a second moving cam having a second trough part and a second crest part that engage the first crest part and the first trough part, respectively, of the second fixed cam;
a first elastic member configured to apply elastic force to the first moving cam such that the first moving cam is pushed toward the first fixed cam; and
a second elastic member configured to apply elastic force to the second moving cam such that the second moving cam is pushed toward the second fixed cam,
wherein the first fixed cam and the second fixed cam are respectively engaged with the first moving cam and the second moving cam if the first flexible body and the second flexible body are fully opened or fully closed.

19. The portable terminal of claim 13, wherein the battery is provided on at least one of the first flexible body and the second flexible body and is a block type battery comprising a plurality of block cells deformable to be bent.

20. The portable terminal of claim 13, wherein the battery is provided on at least one of the first flexible body and the second flexible body and is a laminated battery deformable to be bent.

21. The portable terminal of claim 13, wherein the battery is an integrated battery accommodated in at least one of the first link body and the second link body.

23. The portable terminal of claim 13, wherein the battery is a detachable battery that is attachable to at least one of the first link body and the second link body.

24. The portable terminal of claim 13, further comprising:
a first support plate comprising an elastic material and has a middle part extending inside the first flexible body and an end part connected to the first link body; and
a second support plate comprising an elastic material and has a middle part extending inside the second flexible body and an end part connected to the second link body.
